(19) United States
(12) Patent Application Publication
(10) Pub. No.: US 2024/0177990 A1
(43) Pub. Date: May 30, 2024

(54) OXIDATION CONFORMALITY IMPROVEMENT WITH IN-SITU INTEGRATED PROCESSING

(71) Applicant: Applied Materials, Inc., Santa Clara, CA (US)

(72) Inventors: Hansel LO, San Jose, CA (US); Christopher S. OLSEN, Fremont, CA (US); Erika HANSEN, San Jose, CA (US)

(21) Appl. No.: 18/523,455

(22) Filed: Nov. 29, 2023

Related U.S. Application Data
(60) Provisional application No. 63/428,577, filed on Nov. 29, 2022.

(51) Int. Cl. H01L 21/02

(52) U.S. Cl. CPC H01L 21/02238; H01L 21/0214; H01L 21/02164; H01L 21/02315

(57) ABSTRACT

Methods of treating a substrate are provided. In some embodiments, the method includes exposing a substrate to a vacuum, wherein the substrate has one or more memory holes or trenches. The method further includes treating the substrate with a pre-treatment gas or plasma. The method includes oxidizing the substrate while the substrate is still under the vacuum. In some embodiments, the one or more memory holes have impurity buildup.

### CROSS-REFERENCE TO RELATED APPLICATIONS

This application claims benefit of U.S. Patent Application Ser. No. 63/428,577, filed Nov. 29, 2022, which is incorporated herein by reference.

### BACKGROUND

### Field

Embodiments described herein generally relate to systems and methods for improving the conformality of high aspect ratio (HAR) structures in a semiconductor device. More specifically, the application relates to applying a pre-treatment to a Si-containing surface to decrease the sticking coefficient of the surface, and improve the conformality of the subsequent oxide growth on the Si-containing surface.

### Description of the Related Art

The production of silicon integrated circuits has placed difficult demands on fabrication processes to increase the number of devices while decreasing the minimum feature sizes on a chip. These demands have extended to fabrication processes including depositing layers of different materials onto difficult topologies and etching further features within those layers. Manufacturing processes for next generation NAND flash memory involve especially challenging device geometries and scales. NAND is a type of non-volatile storage technology that does not have need of power to retain data. To increase memory capacity within the same physical space, a three-dimensional NAND (3D NAND) design has been developed. Such a design typically introduces alternating oxide layers and nitride layers, which are deposited on a substrate. The alternating oxide layers and nitride layers are then etched producing a structure having one or more surfaces extending substantially perpendicular to the substrate. Such design considerations have moved the field from processing of relatively low aspect ratio structures, for example 10:1 aspect ratios, to HAR structures, for example 100:1 or greater aspect ratios. These HAR structures are called memory holes or pillars. Prior fabrication processes have included methods for filing gaps in memory holes or slits (trenches) in 3D NAND.

Holes in a memory device often have silicon or silicon nitride (SiₓN_{y}) layers, for example, Si₃N₄, that are to be oxidized conformally. Holes in a memory device may have high or ultra-high aspect ratios, for example, a 40:1 aspect ratio, between a 40:1 and a 100:1 aspect ratio, a 100:1 aspect ratio, or even greater than 100:1 aspect ratio. New fabrication processes are looked-for for conformal deposition of layers on the faces of holes, rather than simply filling gaps and trenches. A more conformal deposition can reduce material build up at the top of the structure. Such material build up may result in material prematurely sealing off the top of the trench between adjacent structures, forming a void in the trench. Unfortunately, slowing the deposition rate also means increasing the deposition time, which reduces processing efficiency and production rates.

Thus, there is a need for improved systems and processes for processing HAR structures.

### SUMMARY

The present disclosure generally relate to systems and methods for improving the conformality of HAR structures in a semiconductor device, for example, a 3D NAND flash device. More specifically, the disclosure relates to applying a pre-treatment to a Si-containing surface to decrease the sticking coefficient of the surface, and improve the conformality of the subsequent oxide growth on the Si-containing surface.

In at least one aspect, a method of treating a substrate is provided. The method includes exposing a substrate to a vacuum, wherein the substrate has one or more memory holes or trenches. The method further includes treating the substrate with a pre-treatment gas or plasma. The method further includes oxidizing the substrate while the substrate is still under the vacuum.

Embodiments may include one or more of the following. At least one of the one or more memory holes or trenches has impurity buildup. The impurity buildup comprises hydrocarbons. The treating the substrate is at a temperature and the temperature is greater than or equal to 50° C. and less than or equal to 850° C. The treating the substrate is at a temperature and the temperature is greater than or equal to 50° C. and less than or equal to 300° C. The substrate comprises Si, SiON, or SiN. The treating the substrate with the pre-treatment gas or plasma is performed for a time ranging from 5 seconds to 3 minutes. The treating the substrate with the pre-treatment gas or plasma is performed in a chamber and the oxidizing the substrate is performed in the chamber. The pre-treatment gas or plasma comprises an inert gas. The inert gas comprises N₂, Ar, He, or a combination thereof. The pre-treatment gas or plasma comprises H₂ or an H· radical. The oxidizing the substrate can be a single-step process. The oxidizing the substrate can be a multi-step process. The treating the substrate is performed at a pressure greater than or equal to 0.1 Torr and less than or equal to atmospheric pressure.

In another aspect, a method of treating a substrate is provided. The method includes exposing a substrate to a vacuum, wherein the substrate has one or more memory holes or trenches. The method further includes treating the substrate with an inert gas. The method further includes oxidizing the substrate while the substrate is still under the vacuum.

Embodiments may include one or more of the following. At least one of the one or more memory holes or trenches has impurity buildup. The treating the substrate is at a temperature, and the temperature is greater than or equal to 50° C. and less than or equal to 300° C. The inert gas has a flow rate of greater than or equal to 10 sccm to 20 slm.

In yet another aspect, a method of treating a substrate is provided. The method includes exposing a substrate to a vacuum, wherein the substrate has one or more memory holes or trenches. The method further includes treating the substrate with a gas comprising H₂ or H· radical. The method further includes oxidizing the substrate while the substrate is still under the vacuum.

Embodiments may include the treating the substrate is at a temperature and the temperature is greater than or equal to 50° C. and less than or equal to 300° C.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a processing sequence in accordance with one or more embodiments of the present disclosure.

FIGS. 2A-2D illustrate cross-sectional views of various stages of increasing the conformality in a memory hole in accordance with one or more embodiments of the present disclosure.

FIG. 3 is a cross-sectional view of an oxidation chamber for performing an oxidation process in accordance with one or more embodiments of the present disclosure.

FIG. 4 is a cross-sectional view of a cleaning chamber used to perform a reducing process in accordance with one or more embodiments of the present disclosure.

FIG. 5 illustrates a plan view of a vacuum processing system in accordance with one or more embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to systems and methods for improving the conformality of HAR structures in a semiconductor device, for example, a 3D NAND flash device. More specifically, the disclosure relates to applying a non-oxidizing pre-treatment to a silicon-containing surface to decrease the sticking coefficient of the surface, and improve the conformality of the subsequent oxide growth on the silicon-containing surface.

3D NAND flash devices significantly magnify the surface area by increasing the aspect ratio of HAR structures on the substrates. These HAR structures often define or include holes, for example, memory holes, word line slits, or trenches. Hereinafter, all discussion of memory holes is also applicable to word line slits and trenches. As the aspect ratio of memory holes continues to increase, it becomes increasingly difficult to grow conformal films within these memory holes. “Conformally” generally refers to uniform and/or constant-thickness layers on faces of structures. In the context of memory holes, “conformally” may be most relevant when discussing the thickness of oxidation on the structure faces that are substantially perpendicular to the substrate. Processes that allow impurities to build up increase the sticking coefficient of oxygen radicals during an oxidation process. For example, often air breaks are unavoidable from one processing operation to another as substrates are moved between processing tools prior to oxidation. During this time, impurities, for example, surface carbon and moisture can accumulate on the silicon-containing surface of the memory hole. A sticking coefficient is the number of atoms or molecules that are reacting on a surface, divided by the total number of collisions of the atoms or molecules with the surface. Increased sticking coefficients result in non-conformal oxide growth in memory holes.

Described herein are systems and methods of utilizing a pre-treatment gas or plasma to reduce the sticking coefficient of the Si-containing surfaces. Utilizing these pre-treatment gases or plasmas may reduce the sticking coefficient of the Si-containing surface of the memory hole by removing the impurity buildup. Further, the conformality of the subsequently formed oxide layer in the memory hole may be improved by 4-5%. In at least one aspect, the methods and systems for reducing the sticking coefficient include non-oxidizing treatment processes such as at least one of a hydrogen bake process, an inert degas process, and a hydrogen radical treatment processes. The non-oxidizing treatment processes are performed in-situ prior to the subsequent oxidation process. In at least one embodiment, the non-oxidizing treatment process is performed in a process chamber integrated on the same cluster tool as the process chamber configured to perform the subsequent oxidation process. In at least another embodiment, the treatment process is performed in-situ in the same chamber as the subsequent oxidation process. This type of in-situ treatment process allows for air break prior to oxidation without major conformality loss.

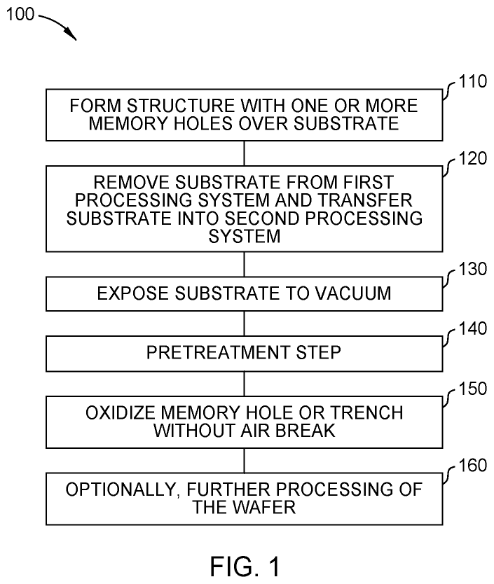

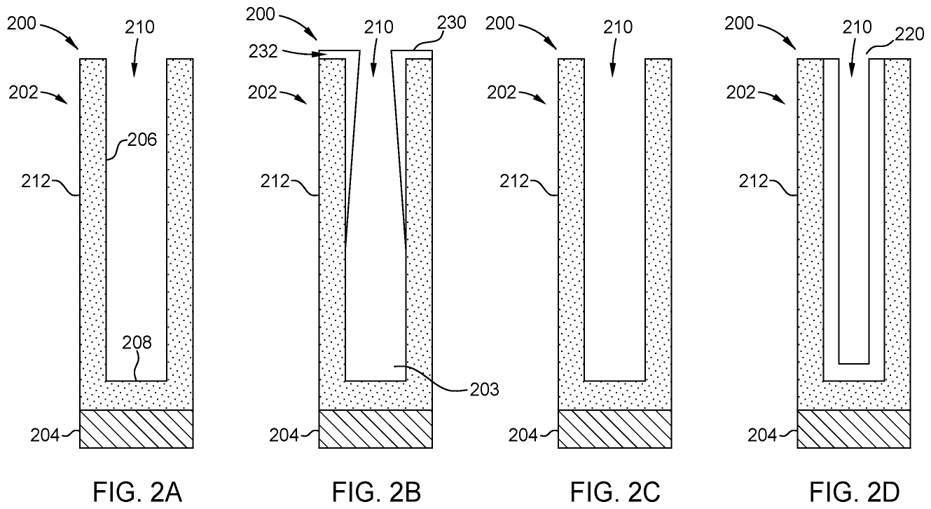

FIG. 1 illustrates an exemplary flow chart of a method 100 of processing one or more memory hole structures in accordance with one or more embodiments of the present disclosure. FIGS. 2A-2D illustrate cross-sectional views of various stages of forming one or more memory hole structures in accordance with one or more embodiments of the present disclosure. With reference to FIGS. 2A-2D, cross-sectional views of some embodiments of a memory hole structure at various stages of manufacture are provided to illustrate the method of FIG. 1. Although FIGS. 2A-2D are described in relation to method 100, it will be appreciated that the structures disclosed in FIGS. 2A-2D are not limited to the method 100, but instead may stand alone as structures independent of method 100. Similarly, although the method 100 is described in relation to FIGS. 2A-2D, it will be appreciated that the method 100 is not limited to the structures disclosed in FIGS. 2A-2D, but instead may stand alone independent of the structures disclosed in FIGS. 2A-2D. For example, the method 100 may be used to form other types of holes, for example, word line slits or trenches in a memory device.

FIG. 2A illustrates a cross-sectional view of a portion of 3D NAND memory device 200 during intermediate stages of manufacturing corresponding to operation 110 of the method 100. It should be understood that the 3D NAND memory device 200 is an example and other types of HAR structures may also benefit from the embodiments described herein. The device 200 includes a memory hole structure 202 formed over a semiconductor substrate 204. At operation 110, the memory hole structure 202 is formed over the semiconductor substrate 204. Operation 110 or portions of operation 110 may be performed in a first processing chamber or a first processing system (not shown).

The semiconductor substrate 204 may be any suitable starting material for forming integrated circuits, such as a silicon (Si) wafer or a germanium (Ge) wafer. The semiconductor substrate 204 may be a silicon semiconductor substrate having a layer or layers formed thereon, such as a film stack, employed to form a structure on the semiconductor substrate 204, such as the 3D NAND memory device 200. The semiconductor substrate 204 may include a material such as crystalline silicon (e.g., Si<100> or Si<111>), silicon oxide, strained silicon, silicon germanium, doped or undoped polysilicon, doped or undoped silicon, patterned or non-patterned wafer, silicon on insulator (SOI), carbon-doped silicon oxides, silicon nitride, doped silicon, germanium, gallium arsenide, glass, sapphire, metal layers disposed on silicon, and the like. The semiconductor substrate 204 may be configured as a 200 mm, 300 mm, or 450 mm diameter wafer, or as a rectangular or square panel.

The memory hole structure 202 includes sidewalls 206 and a bottom surface 208, which define a memory hole 210. The memory hole structure 202 may further include a plurality of memory cells alternately stacked between a plurality of insulating layers which are not shown for the sake of brevity. The sidewalls 206 and optionally the bottom surface 208 are defined by a silicon-containing film 212. Any suitable silicon-containing film may be used. The silicon-containing film 212 may be a silicon film, a silicon oxynitride (SiOₓN_{y}) film, or a silicon nitride (SiₓN_{y}) film. Any suitable process may be used to deposit the silicon-containing film 212. In at least one embodiment, the silicon-containing film 212 may be deposited via an atomic layer deposition (ALD) process. For example, an ALD SiN deposition process or an ALD Si deposition process. Operation 110 may be performed by a deposition tool, for example, an ALD tool (not shown). Operation 110 is typically performed in a separate processing system than the processing chamber that is utilized to oxidize the memory device 200.

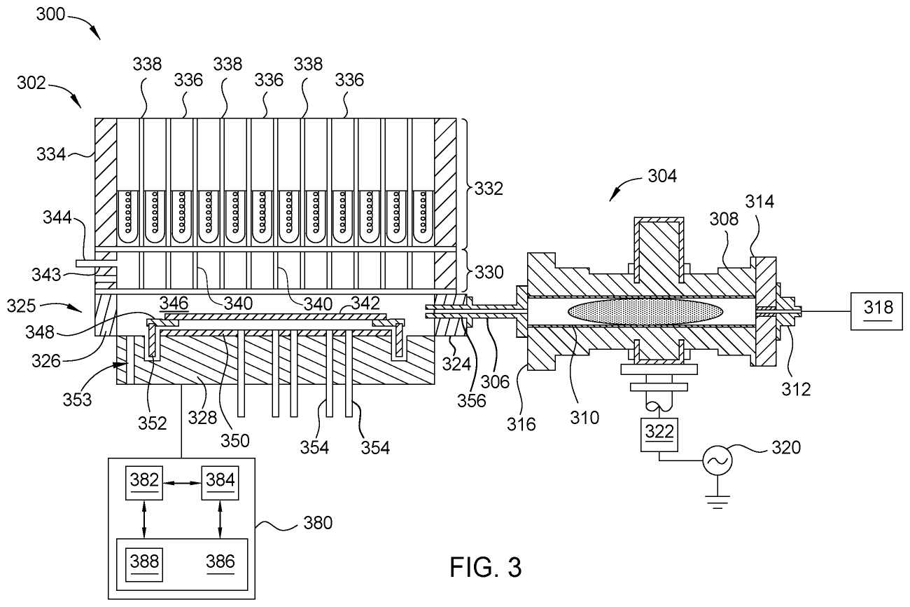

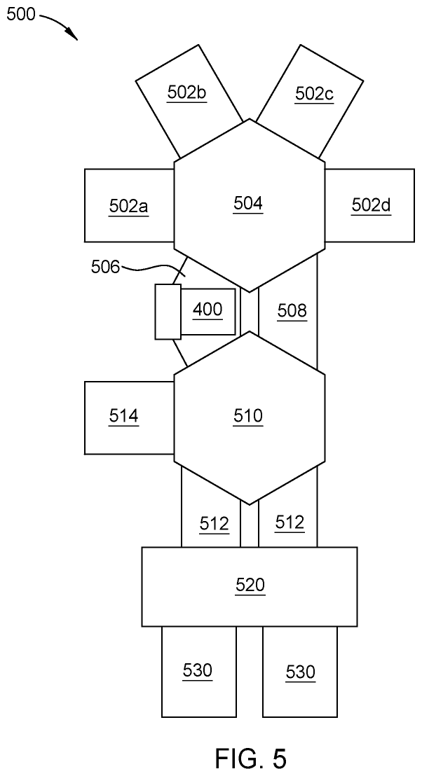

FIG. 2B illustrates a cross-sectional view of the portion of the 3D NAND memory device 200 during intermediate stages of manufacturing corresponding to operation 120 of the method 100. After operation 110, during operation 120, the device 200 is removed from the first processing system (not shown) and transferred to a second processing system used for operations 130, 140, 150, 160 (discussed in more detail in the description of FIGS. 3-5). In at least one embodiment, the second processing system includes a vacuum processing system, for example, the vacuum processing system 500 depicted in FIG. 5. In at least one embodiment, the second processing system includes a standalone vacuum process chamber, for example, the processing system 300 depicted in FIG. 3. In operation 120, the device 200 may be transferred immediately, or there may be an indefinite period of time before the substrate is introduced to the processing chamber. During operation 120, the exposure to the air and humidity may cause impurity buildup on the memory hole. FIG. 2B illustrates the memory device 200 during and after operation 120, where impurity buildup 230 has formed on the surface of the silicon-containing film 212. The impurity buildup 230 may be more expansive if the substrate is exposed to air for longer periods. The impurity buildup 230 may also be more expansive if the substrate is exposed to more humid conditions. It should be noted that FIG. 2B illustrates an exemplary embodiment of the impurity buildup 230. In other embodiments, the impurity buildup 230 may be less regular, more concentrated along the silicon-containing film 212 at a top 232 of the memory hole 210, extend further into the silicon-containing film 212, larger, or smaller. Due to the dimensions of the memory hole 210, the impurity buildup 230 will naturally be more concentrated at the top of the silicon-containing film 212 than at the bottom 203 of the silicon-containing film 212. In some embodiments, the impurity buildup 230 includes contaminants such as carbon, hydrocarbons, moisture, or combinations thereof.

After the device 200 is transferred to the second processing system, the device 200 is exposed to a vacuum in operation 130.

FIG. 2C illustrates a cross-sectional view of the portion of 3D NAND memory device 200 during intermediate stages of manufacturing corresponding to operation 140 of the method 100. During the pretreatment process of operation 140, while the substrate is under vacuum, the substrate is exposed to pre-treatment gas or plasma in operation 140. The pre-treatment gas or plasma may be inert gas, H₂, H· radicals, or any combination thereof. The pre-treatment gas or plasma may be a non-oxidizing pre-treatment gas or plasma. The inert gas may contain nitrogen (N₂), argon (Ar), or helium (He). The inert gas may also be a mixture of N₂, Ar, and He, where the percentage of each gas in the mixture is anywhere from 0% to 100%.

The non-oxidizing treatment processes of operation 140 is performed in-situ prior to the subsequent oxidation process of operation 150. In at least one embodiment, the non-oxidizing treatment process of operation 140 is performed in a process chamber, for example, the processing system 400, integrated on the same cluster tool, for example, the vacuum processing system 500, as the process chamber, for example, the processing system 300, configured to perform the subsequent oxidation process. In at least another embodiment, the treatment process is performed in-situ in the same processing system 300 as the subsequent oxidation process.

While the substrate is under vacuum, the substrate is exposed to pre-treatment gas or plasma in operation 140. The pre-treatment gas or plasma may be inert gas, H₂, or H· radicals. The inert gas may contain nitrogen (N₂), argon (Ar), or helium (He). The inert gas may also be a mixture of N₂, Ar, and He, where the percentage of each gas in the mixture is anywhere from 0% to 100%.

During operation 140, the flowrate of pre-treatment gas or plasma may be anywhere from 10 sccm to 20 slm. In other embodiments, the flowrate of the pre-treatment gas or plasma may range from 1 sim to 10 slm.

During operation 140, the pressure of the processing chamber may be from 0.1 Torr to atmospheric pressure. In other embodiments, the pressure of the processing chamber may 0.5 Torr to 100 Torr, for example, from about 2 Torr to about 100 Torr.

During operation 140, the temperature of the pre-treatment gas or plasma may be greater than or equal to 50° C. and less than or equal to 800° C. Additionally, the substrate may be maintained at or near the temperature of the pre-treatment gas. In other embodiments, the temperature of the pre-treatment gas or plasma may be greater than or equal to 50° C. and less than or equal to 300° C. In yet other embodiments, the temperature of the pre-treatment gas or plasma may be greater than or equal to 150° C. and less than or equal to 300° C.

Operation 140 may be performed for a period of 5 seconds to 3 minutes. In another embodiment, operation 140 may be performed for a period of 10 seconds to 1 minute.

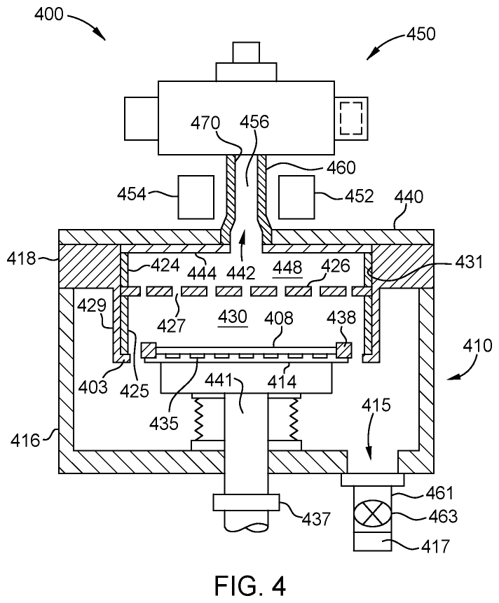

In at least one embodiment, where operation 140 comprises a radical treatment process, the H· radicals may be formed by flowing hydrogen gas (H₂) into a remote plasma source, for example, the remote plasma source 304 or the remote plasma source 450 described more below in FIGS. 3 and 4. The remote plasma source may be fluidly coupled to the processing volume and igniting and maintaining a plasma of the hydrogen gas to form the hydrogen radicals thereof. The hydrogen radicals may then be flowed into the processing volume. In other embodiments, a remote plasma may be formed in a portion of a processing volume of a processing chamber that is separated from the portion of the processing volume having the substrate disposed therein. For example, in those embodiments, the remote plasma may be formed in a portion of a processing volume that is separated from the substrate processing portion by a showerhead.

In at least another embodiment, where operation 140 comprises a thermal treatment process, the thermal treatment process may be performed to remove any residual by-products or contaminants from the processing volume. During the thermal treatment process of operation 140, the processing volume is maintained under vacuum conditions, such as less than or equal to atmospheric pressure, for example, 760 Torr or less, less than about 700 Torr, less than about 600 Torr, less than about 500 Torr, less than about 400 Torr, less than about 300 Torr, or less than about 200 Torr. In some embodiments, the processing volume is maintained at a pressure in a range from about 0.1 Torr to about 760 Torr, or in a range from about 2 Torr to about 760 Torr, or in a range from about 400 Torr to about 600 Torr, or in a range from about 500 Torr to about 530 Torr. During the thermal treatment process, the hydrogen gas (e.g., H₂) may be flowed into the processing volume at a flowrate from about 10 sccm to about 20 slm. The hydrogen gas may be introduced into the processing volume with an inert gas. In one embodiment, treatment gas mixture includes hydrogen in a range from about 0.1% to about 100% with the remainder being an inert carrier gas such as argon, helium, or xenon. In one example, the treatment gas mixture includes hydrogen gas in a range from about 90% to about 100% for example, 100% hydrogen. In some embodiments, the treatment time, here the amount of time the device 200 is maintained at the thermal treatment temperature is about 5 seconds or more, 20 seconds or more, such as about 30 seconds or more, about 40 seconds or more, about 50 seconds or more, about 1 minute or more, about 1.5 minutes or more, about 2 minutes or more, about 2.5 minutes or more, about 3 minutes of more, about 3.5 minutes or more, about 4 minutes or more, about 4.5 minutes or more, e.g., about 5 minutes or more.

In at least one embodiment, after operation 140, the memory device 200 is oxidized in the same chamber in operation 150. As shown in FIG. 2D, operation 150 forms an oxide layer 220 on the silicon-containing film 212. The oxide layer 220 may comprise silicon dioxide (SiO₂) or silicon oxynitride (SiOₓN_{y} where x and y are integers). The oxide layer 220 may be larger or smaller based on the conditions of operation 150 (discussed more below). The thickness of the oxide layer may range from 5 Å to 15 nm.

The oxide layer 220 may be formed by introducing oxygen (O₂) or a mixture of oxygen and a second gas into the oxidation chamber (discussed more below in the description of FIGS. 3-5). In some embodiments, the second gas may be hydrogen (H₂), argon (Ar), nitrogen (N₂), helium (He), or any combination thereof.

The oxidation in operation 150 may be performed in a single step or in multiple steps. In one embodiment, a single step oxidization in operation 150 may be performed at a temperature greater than or equal to 500° C. and less than or equal to 800° C. In another embodiment, a multi-step oxidization in operation 150 may be performed with a first step performed at a temperature of 500° C. and a second step at a temperature of 800° ° C. In a multi-step oxidization process, the first step may be performed slower to improve the conformality of the oxide layer 220. In yet another embodiment, the multi-step oxidation process in operation 150 may be performed with a first step at a temperature of 500° C., a second step at a temperature of 600° C., a third step at a temperature of 700° C., and a fourth step at a temperature of 800° C. In this embodiment, the gradual increase in temperature may improve the conformality of the oxide layer 220. In another embodiment, the oxidation in operation 150 may be performed at a temperature of 800° C., and a non-temperature variable is modified. In some embodiments, the non-temperature variable may be oxidant species, gas ratio, or dilution with non-oxidizing gas including hydrogen (H₂), argon (Ar), nitrogen (N₂), or helium (He) or any combination thereof.

In at least one embodiment, the treatment process of operation 140 is performed in a process chamber integrated on the same cluster tool as the process chamber configured to perform the subsequent oxidation process of operation 150. In at least another embodiment, the treatment process of operation 140 is performed in-situ in the same process chamber as the subsequent oxidation process of operation 150. The in-situ treatment process of operation 140 allows for air break prior to the oxidation process of operation 150 without major conformality loss.

After the oxidization step in operation 150, the substrate with the one or more memory holes may undergo further processing in operation 160.

FIG. 3 is a cross-sectional view of an exemplary processing system 300 that may be utilized in operations 120, 130, 140, 150, 160. The processing system 300 includes a processing chamber 302 and a remote plasma source 304. The processing chamber 302 may be a rapid thermal processing (RTP) chamber. The processing system 300 may be configured to perform the non-oxidizing pretreatment process of operation 140 and the oxidation process of operation 150. The remote plasma source 304 may be any suitable remote plasma source, such as microwave coupled plasma source, that can operate at a power, for example, of about 6 kW. The remote plasma source 304 is coupled to the processing chamber 302 to flow plasma formed in the remote plasma source 304 toward the processing chamber 302. The remote plasma source 304 is coupled to the processing chamber 302 via a connector 306. Radicals formed in the remote plasma source 304 flow through the connector 306 into the processing chamber 302 during processing of a substrate.

The remote plasma source 304 includes a body 308 surrounding a tube 310 in which plasma is generated. The tube 310 may be fabricated from quartz or sapphire. The body 308 includes a first end 314 coupled to an inlet 312, and one or more gas sources 318 may be coupled to the inlet 312 for introducing one or more gases into the remote plasma source 304. In one embodiment, the one or more gas sources 318 include an oxygen containing gas source, and the one or more gases include an oxygen containing gas. The body 308 includes a second end 316 opposite the first end 314, and the second end 316 is coupled to the connector 306. A coupling liner (not shown) may be disposed within the body 308 at the second end 316. A power source 320 (e.g., an RF power source) may be coupled to the remote plasma source 304 via a match network 322 to provide power to the remote plasma source 304 to facilitate the forming of the plasma. The radicals in the plasma are flowed to the processing chamber 302 via the connector 306.

The processing chamber 302 includes a chamber body 325, a substrate support portion 328, and a window assembly 330. The chamber body 325 includes a first side 324 and a second side 326 opposite the first side 324. In some embodiments, a lamp assembly 332 enclosed by an upper sidewall 334 is positioned over and coupled to the window assembly 330. The lamp assembly 332 may include a plurality of lamps 136 and a plurality of tubes 338, and each lamp 336 may be disposed in a corresponding tube 338. The window assembly 330 may include a plurality of light pipes 340, and each light pipe 340 may be aligned with a corresponding tube 338 so the thermal energy produced by the plurality of lamps 336 can reach a substrate disposed in the processing chamber 302. In some embodiments, a vacuum condition can be produced in the plurality of light pipes 340 by applying a vacuum to an exhaust 344 fluidly coupled to the plurality of light pipes 340. The window assembly 330 may have a conduit 343 formed therein for circulating a cooling fluid through the window assembly 330.

A processing volume 346 may be defined by the chamber body 325, the substrate support portion 328, and the window assembly 330. A substrate 342 is disposed in the processing volume 346 and is supported by a support ring 348 above a reflector plate 350. The support ring 348 may be mounted on a rotatable cylinder 352 to facilitate rotating of the substrate 342. The cylinder 352 may be levitated and rotated by a magnetic levitation system (not shown). The reflector plate 350 reflects energy to a backside of the substrate 342 to facilitate uniform heating of the substrate 342 and promote energy efficiency of the processing system 300. A plurality of fiber optic probes 354 may be disposed through the substrate support portion 328 and the reflector plate 350 to facilitate monitoring a temperature of the substrate 342.

A liner assembly 356 is disposed in the first side 324 of the chamber body 325 for radicals to flow from the remote plasma source 304 to the processing volume 346 of the processing chamber 302. The liner assembly 356 may be fabricated from a material that is oxidation resistant, such as quartz, in order to reduce interaction with process gases, such as oxygen radicals. The liner assembly 356 is designed to reduce flow constriction of radical flowing to the processing chamber 302. The liner assembly 356 is described in detail below. The processing chamber 302 further includes a distributed pumping structure 333 formed in the substrate support portion 328 adjacent to the second side 326 of the chamber body 325 to tune the flow of radicals from the liner assembly 356 to the pumping ports. The distributed pumping structure 333 is located adjacent to the second side 326 of the chamber body 325.

A controller 380 may be coupled to various components of the processing system 300, such as the processing chamber 302 and/or the remote plasma source 304 to control the operation thereof. The controller 380 generally includes a central processing unit (CPU) 382, a memory 386, and support circuits 384 for the CPU 382. The controller 380 may control the processing system 300 directly, or via other computers or controllers (not shown) associated with particular support system components. The controller 380 maybe one of any form of general-purpose computer processor that can be used in an industrial setting for controlling various chambers and sub-processors. The memory 386, or computer-readable medium, may be one or more of readily available memory such as random access memory (RAM), read only memory (ROM), floppy disk, hard disk, flash drive, or any other form of digital storage, local or remote. The support circuits 384 are coupled to the CPU 382 for supporting the processor in a conventional manner. The support circuits 384 include cache, power supplies, clock circuits, input/output circuitry and subsystems, and the like. Processing steps may be stored in the memory 386 as software routine 388 that may be executed or invoked to turn the controller 380 into a specific purpose controller to control the operations of the processing system 300. The controller 380 may be configured to perform any methods described herein, for example, the method 100.

FIG. 4 is a cross sectional view of an exemplary processing chamber 400 that may be utilized in operations 140. The processing chamber 400 may be configured to perform a hydrogen radical treatment process. The processing chamber 400 has a chamber body 410, which includes a chamber enclosure 416, a process kit housing 418, and a lid 440. The chamber enclosure 416 and the lid 440 may be fabricated from aluminum, stainless steel, or other suitable materials. The process kit housing 418 may be fabricated from aluminum alloy or other suitable materials. The lid 440 is removably coupled to the chamber enclosure 416 through the process kit housing 418.

The process kit housing 418 may be a ring-shaped housing having a top surface that couples to the lid 440 and a bottom surface that couples to the chamber enclosure 416. The process kit housing 418 has a shield portion 429 extending down from an inner surface 431 of the process kit housing 418. The inner surface 431 of the process kit housing 418 surrounds and supports a gas distribution plate 426 thereon. The gas distribution plate 426 may be a quartz showerhead. A plenum 448 is defined between the gas distribution plate 426 and the lid 440. The gas distribution plate 426 includes a plurality of apertures 427 formed through the thickness of the gas distribution plate 426 to allow gases flowing into the plenum 448 through a port 442. The apertures 427 are evenly distributed across the diameter of the gas distribution plate 426 to ensure uniform distribution of the gases or radicals to the substrate 408. The gases flowing through the apertures 427 are distributed across the substrate 408 disposed in a process region 430 defined between the gas distribution plate 426 and a substrate support 414. The substrate support 414 may include a heater. The shield portion 429 also helps confine electrically neutral radicals within the process region 430. In one example, the shield portion 429 is extended to a location adjacent or below the edge of the substrate support 414.

The processing chamber 400 includes a remote plasma source 450 that is coupled to the port 442 by a conduit 460. The port 442 is formed in the lid 440. The conduit 460 defines an inlet 456, which may have a first inner diameter and a second inner diameter that is larger than the first inner diameter. The first inner diameter may be disposed adjacent to the remote plasma source 450 and the second inner diameter may be disposed adjacent to the lid 440. In one example, first inner diameter may be about 12 mm to about 30 mm, for example about 20 mm, and the second inner diameter may be about 35 mm to about 60 mm, for example about 40 mm.

The conduit 460 is configured to filter ions generated in the remote plasma source 450 before entering the process region 430, while allowing electrically neutral radicals to enter the process region 430. The relative concentration of ions in the process region 430 is thus reduced. In one embodiment, the gases flowing through the inlet 456 are filtered by a magnetic field generated by one or more magnets disposed adjacent to the conduit 460. The magnets generate a magnetic field across the conduit 460 to filter charged particles entrained with the reactive radicals flowing from the remote plasma source 450.

In the embodiment depicted in FIG. 4, a first magnet 452 and a second magnet 454 are disposed adjacent to the conduit 460. The first magnet 452 and second magnet 454 may be permanent magnets or electromagnets. The magnets 452, 454 may be disposed opposite from each other across the first inner diameter of the conduit 460. For example, the magnets 452, 454 may be adhered or secured on opposite sides of an outer periphery of the conduit 460. The magnets 452, 454 may alternately be secured to the chamber lid 440 or other components of the chamber body 410. The relative distance between the opposed magnet and the inlet 456 formed within the conduit 460 affects the strength of the magnetic field passing through the inlet 456, and thereby affects the filtering efficiency. The magnetic field may also be adjusted by using different magnets, i.e., replacing magnets 452, 454 with different strength. The passing charged particles are drawn in contact with an inner surface 470 of the conduit 460 and become electrically neutral, non-ionic species. As such, the filtered, electrically neutral radicals are delivered to the surface of the substrate to react with and clean contaminants thereon.

In some embodiments, the ions may be further filtered by providing a quartz surface in the flow path of the process gases (i.e., radicals and ions) passing into the chamber body 410. For example, the inner surface 470 of the conduit 460 defining the inlet 456 may be entirely or partially coated or fabricated from quartz. Additionally, the surfaces defining the plenum 448 and/or gas distribution plate 426 may also be entirely or at least partially coated or fabricated from quartz. For example, in the embodiment of FIG. 4, a top liner 424 may be disposed along the inner surface 431 of the process kit housing 418. The top liner 424 may have a ring-shaped body surrounding the plenum 448, an inner surface thereof defining the outer boundary of the plenum 448. The top liner 424 may be made of quartz. The top liner 424 may rest on the gas distribution plate 426, or may be supported by any other suitable securing approach.

A liner plate 444 may be disposed along the bottom surface of the lid 440. The liner plate 444 may be coated with, or fabricated from, quartz. The liner plate 444 defines the upper boundary of the plenum 448. Therefore, the liner plate 444, the top liner 424, and the gas distribution plate 426 define the plenum 448. A bottom liner 425 may be disposed along the inner surface 431 of the process kit housing 418. The bottom liner 425 may have a ring-shaped body, and surrounds the process region 430 when assembled for operation, an inner surface thereof defining the outer boundary of the process region 430. The bottom liner 425 may be coated with, or fabricated from, quartz. The bottom liner 425 may be supported by the shield portion 429. In one example as shown, a ledge 403 extends radially inward at an end of the shield portion 429 to support the bottom liner 425. Therefore, the conduit 460, the liner plate 444, the top liner 424, the bottom liner 425, and the gas distribution plate together provide a quartz surface along the flow path of the process gases. These components reduce the recombination of radicals as compared to other chamber materials (e.g., aluminum). As such, the process gas is substantially reduced in content of charged particles, and may be predominantly neutral species such as radicals and molecules, when flowing through the gas distribution plate 426 into the process region 430. The electrically neutral radicals will remain reactive when they reach and react with a surface of the substrate disposed on the substrate support to remove unwanted materials, for example carbon contaminants, from the surface of the substrate.

A substrate support 414 is disposed in the process region 430 of the chamber body 410. The substrate support 414 is coupled to a bottom of the chamber enclosure 416 through a central shaft 441. The substrate support 414 has a substrate supporting surface for supporting the substrate 408 thereon during a process, such as the processes described above with respect to operations 120, 130, 140, 150, 160. An optional focus ring 438 may be disposed on the substrate support 414 around the outer periphery of the substrate supporting surface. The focus ring 438 confines plasma or neutral species in an area above the substrate 408 during the processes. The focus ring 438 may be fabricated from quartz.

The substrate support 414 may be fabricated from aluminum with a plurality of sapphire contacts (not shown) disposed on the substrate supporting surface to minimize contact between the substrate supporting surface and a substrate disposed on the sapphire contacts. The substrate support 414 is actuated by a driving unit 437 to move vertically between a loading position and a processing position. The substrate support 414 may have one or more heating elements 435 embedded therein to provide uniform thermal energy to the substrate supporting surface. Suitable heating elements 435 may include resistive heaters, thermoelectric devices, or conduits for flowing heat transfer fluid, among other heating devices. The heating elements 435 allow the temperature of the substrate 408 to be maintained during the processes. In some embodiments, the substrate support 414 may have cutouts formed through the peripheral edge of the substrate supporting surface so that a substrate handler (not shown) can manipulate the substrate 408 from the edge of the substrate when the substrate support 414 is positioned at the loading position. During the cleaning process, the substrate support 414, with substrate 408 disposed thereon, is positioned at the processing position, which is a desired position for processing the substrate 408.

The processing chamber 400 includes a pump 417. The pump 417 is connected to the chamber body 410 through a foreline 461. The foreline 461 connects to the chamber body 410 at an opening 415 formed at the bottom of the chamber enclosure 416. The processing chamber 400 also includes a throttle valve 463 disposed in the foreline 461. The throttle valve 463 is operated to open and close to whatever extent is necessary to maintain the pressure in the processing chamber 400 in a desired vacuum range for the plasma cleaning process being run. The pump 417 and the throttle valve 463 control the pressure inside the chamber body 410. In some examples, the pump 417 is a dry pump, a low-pressure pump, or a turbo pump.

FIG. 5 illustrates an exemplary vacuum processing system 500 that can be used to complete the method 100 illustrated in FIG. 1, according to embodiments of the present disclosure. As shown in FIG. 5, a plurality of processing chambers 502a, 502b, 502c, 502d are coupled to a first transfer chamber 504. The processing chambers 502a-502d may be used to perform any substrate related processes, such as annealing, chemical vapor deposition, physical vapor deposition, epitaxial process, etching process, substrate pre-treatment, thermal oxidation or thermal nitridation process, degassing etc. In one embodiment, the processing chamber 502a may be a film formation chamber, such as a vapor phase epitaxy deposition chamber, for example, an Epi chamber available from Applied Materials, Santa Clara, California. In another embodiment, the processing chamber 502a may be a processing chamber that can be adapted to perform a reducing process. Any of the processing chambers 502a-502d may be a Radiance® H2 Bake (RTH) chamber, available from Applied Materials, Inc. Chambers from other manufacturers may also be used. In embodiments where one of the processing chambers 502a-502d is an RTH chamber, one of the remaining processing chambers 502a-502d is an oxidation chamber, for example, the processing chamber 302.

The processing chamber 502b may be a rapid thermal processing chamber (RTP). The processing chamber 502c may be a plasma etching chamber or a plasma cleaning chamber. For example, the processing chamber 502b may be the processing chamber 302 described in connection with FIG. 3. The processing chamber 502d may be a degassing chamber. The first transfer chamber 504 is also coupled to at least one transition station, for example a pair of passthrough stations 506, 508. The pass-through stations 506, 508 maintain vacuum conditions while allowing substrates to be transferred between the first transfer chamber 504 and a second transfer chamber 510. The first transfer chamber 504 has a robotic substrate handling mechanism (not shown) for transferring substrates between the pass-through stations 506, 508 and any of the processing chambers 502a-502d. The processing chambers 502a-502d are shown configured in a certain order in FIG. 5, but they may be configured in any desired order.

One end of the pass-through stations 506, 508 is coupled to the second transfer chamber 510. Therefore, the first transfer chamber 504 and the second transfer chamber 510 are separated and connected by the pass-through stations 506, 508. The second transfer chamber 510 is coupled to a plasma-cleaning chamber 514, which can be a plasma chamber such as a processing chamber that is adapted to perform operation 140 found in FIG. 1 for removing impurities from a Si-containing surface of a substrate. In one embodiment, the plasma-cleaning chamber 514 is a Siconi™ or Selectra™ chamber, which is available from Applied Materials, Santa Clara, Calif. In another embodiment, the plasma-cleaning chamber 514 may be the processing chamber 302 described in connection with FIG. 3 or the processing chamber 400 described in connection with FIG. 4.

In one embodiment, the at least one transition station, for example one of the pass-through stations 506, 508, is configured to perform a reducing process such as an AKTIV Pre-Clean™, PCxT Reactive Preclean™ (RPC), or Selectra™ chamber, available from Applied Materials, Inc. Alternatively, a plasma-cleaning chamber may be coupled to one of the pass-through stations 506, 508 for removing impurities from the surface of the Si-containing substrate. Thus, the vacuum processing system 500 may have a reducing process chamber that is, or is connected to, one of the pass-through stations 506, 508. In one embodiment shown in FIG. 5, the pass-through station 506 includes a reducing process chamber 400. The reducing process chamber 400 may be a version of the processing chamber 400 (FIG. 4) that is adapted to perform at least operation 140 for removing impurities from the Si-containing surface of the substrate. It should be noted that, although only one reducing process chamber 400 is shown coupled to a pass-through station, in this case the pass-through station 506, a plasma-cleaning chamber (e.g., a version of the processing chamber 302 or the processing chamber 400) may be coupled to both the pass-through stations 506 and 508.

The second transfer chamber 510 also has a robotic substrate handling mechanism (not shown) for transferring substrates between a set of load lock chamber 512 and the plasma-cleaning chamber 514 or the reducing process chamber 400. A factory interface 520 is connected to the second transfer chamber 510 by the load lock chambers 512. The factory interface 520 is coupled to one or more pods 530 on the opposite side of the load lock chambers 512. The pods 530 typically are front opening unified pods (FOUP) that are accessible from a clean room (not shown).

While two transfer chambers are shown, it is contemplated that any of the transfer chambers may be omitted. In one embodiment where the second transfer chamber 510 is omitted, the reducing process chamber 400 may be disposed within or coupled to the first transfer chamber 504 at the location currently shown as occupied by the pass-through stations 506 or 508. The first transfer chamber 504 may be coupled to one or more processing chambers capable of forming crystalline silicon or silicon germanium, such as an epitaxy chamber, for example a Centura™ Epi chamber available from Applied Materials, Inc., of Santa Clara, Calif. Alternatively, the first transfer chamber 504 may be omitted and the reducing process chamber 400 may be disposed within or coupled to the pass-through station 506, which is coupled to the second transfer chamber 510.

In operation, substrates are carried from pods 530 to the vacuum processing system 500 in a transport cassette (not shown) that is placed within one of the load lock chambers 512. The robotic transport mechanism within the second transfer chamber 510 transports the substrates, one at a time, from the load lock chambers 512 to the plasma-cleaning chamber 514 where a cleaning process, is performed to remove oxides from a surface of a substrate. Once the oxides have been removed from the substrate surface, the robotic transport mechanism disposed within the second transfer chamber 510 transfers the substrate from the plasma-cleaning chamber 514 to the reducing process chamber 400 where a reducing process, e.g., processes found in operation 140, is performed to remove impurities such as carbon or hydrocarbons from the substrate surface. The clean substrates are then transferred by the robotic transport mechanism disposed within the first transfer chamber 504 from the reducing process chamber 400 to one or more processing chambers 502a-502d where an oxidation process, for example, the oxidation process of operation 150, is performed.

Upon completion of processing in the one or more processing chambers 502a-502d, the robotic transport mechanism disposed within the first transfer chamber 504 moves the substrate from either one of the processing chambers 502 to the pass-through station 508. The substrate is then removed from the pass-through station 508 by the robotic transport mechanism disposed within the second transfer chamber 510 and transferred to the other load lock chamber 512 through which it is withdrawn from the vacuum processing system 500.

Since the processes of operations 130, 140, 150, 160 are performed within the same vacuum processing system 500, vacuum is not broken as the substrate is transferred among various chambers, which decreases the chance of contamination and improves the conformality of the memory hole. It should be understood that the movement of the substrates is described herein for illustration purposes. A controller (not shown) may be used to schedule the movement of the substrates through the vacuum processing system 500 in accordance with a desired sequencing program, which may vary depending upon the application.

In the Summary above and in the Detailed Description, and the claims below, and in the accompanying drawings, reference is made to particular features (including method operations) of the present disclosure. It is to be understood that the disclosure in this specification includes all possible combinations of such particular features. For example, where a particular feature is disclosed in the context of a particular aspect or embodiment of the present disclosure, or a particular claim, that feature can also be used, to the extent possible in combination with and/or in the context of other particular aspects and embodiments of the present disclosure, and in the present disclosure generally.

The terms “comprising,” “including,” “having,” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

While the foregoing is directed to embodiments of the present disclosure, other and further embodiments of the disclosure may be devised without departing from the basic scope thereof, and the scope thereof is determined by the claims that follow.

1. A method of treating a substrate, comprising:
exposing a substrate to a vacuum, wherein the substrate has one or more memory holes or trenches;
treating the substrate with a pre-treatment gas or plasma; and
oxidizing the substrate while the substrate is still under the vacuum.

2. The method of claim 1, wherein at least one of the one or more memory holes or trenches has impurity buildup.

3. The method of claim 2, wherein the impurity buildup comprises hydrocarbons.

4. The method of claim 1, wherein the treating the substrate is at a temperature, and the temperature is greater than or equal to 50° C. and less than or equal to 850° C.

5. The method of claim 1, wherein the treating the substrate is at a temperature, and the temperature is greater than or equal to 50° C. and less than or equal to 300° C.

6. The method of claim 1, wherein the substrate comprises Si, SiOₓN_{y}, or SiN.

7. The method of claim 1, wherein the treating the substrate with the pre-treatment gas or plasma is performed for a time ranging from 5 seconds to 3 minutes.

8. The method of claim 1, wherein the treating the substrate with the pre-treatment gas or plasma is performed in a chamber and the oxidizing the substrate is performed in the chamber.

9. The method of claim 1, wherein the pre-treatment gas or plasma comprises an inert gas.

10. The method of claim 9, wherein the inert gas comprises N₂, Ar, He, or a combination thereof.

11. The method of claim 1, wherein the pre-treatment gas or plasma comprises H₂ or an H· radical.

12. The method of claim 1, wherein the oxidizing the substrate is a single-step process.

13. The method of claim 1, wherein the oxidizing the substrate is a multi-step process.

14. The method of claim 1, wherein the treating the substrate is performed at a pressure greater than or equal to 0.1 Torr and less than or equal to atmospheric pressure.

15. A method of treating a substrate, comprising:
exposing a substrate to a vacuum, wherein the substrate has one or more memory holes or trenches;
treating the substrate with an inert gas; and
oxidizing the substrate while the substrate is still under the vacuum.

16. The method of claim 15, wherein at least one of the one or more memory holes or trenches has impurity buildup.

17. The method of claim 15, wherein the treating the substrate is at a temperature, and the temperature is greater than or equal to 50° C. and less than or equal to 300° C.

18. The method of claim 15, wherein the inert gas has a flow rate of greater than or equal to 10 sccm to 20 slm.

19. A method of treating a substrate, comprising:
exposing a substrate to a vacuum, wherein the substrate has one or more memory holes or trenches;
treating the substrate with a gas comprising H₂ or H· radical; and
oxidizing the substrate while the substrate is still under the vacuum.

20. The method of claim 19, wherein the treating the substrate is at a temperature, and the temperature is greater than or equal to 50° ° C. and less than or equal to 300° C.
